(19) United States
(12) Patent Application Publication
(10) Pub. No.: US 2015/0140836 A1
(43) Pub. Date: May 21, 2015

(54) Methods to Control SiO2 Etching During Fluorine Doping of Si/SiO2 Interface

(71) Applicant: Intermolecular, Inc., San Jose, CA (US)

(72) Inventor: Sandip Niyogi, San Jose, CA (US)

(73) Assignee: Intermolecular, Inc., San Jose, CA (US)

(21) Appl. No.: 14/083,117

(22) Filed: Nov. 18, 2013

(51) Int. Cl. H01L 21/02

(52) U.S. Cl. CPC H01L 21/02321; H01L 21/02164; H01L 21/0234
USPC 438/779; 438/783

(57) ABSTRACT

Methods and apparatus for processing using a remote plasma source are disclosed. The apparatus includes an outer chamber enclosing a substrate support, a remote plasma source, and a showerhead. A substrate heater can be mounted in the substrate support. A transport system moves the substrate support and is capable of positioning the substrate. Methods are disclosed that discuss the use of blocking species that bind to the surface of the dielectric and retard the etching of the dielectric surface by a doping/passivating species. The surface of the dielectric may be exposed to the blocking species a plurality of times during the process to ensure that the surface is well protected.

### TECHNICAL FIELD

The present disclosure relates generally to methods and apparatuses for processing using a remote plasma source for surface treatment, cleaning, and layer formation.

### BACKGROUND

Plasmas are widely used for a variety of treatment and layer deposition tasks in semiconductor fabrication and other thin film applications. These applications include subtractive processes such as doping, wafer precleaning, contaminant removal, native oxide removal, photoresist removal, plasma etching, as well as treatment processes such as oxidation, nitridation, or hydridation of a layer both during and after formation. “Remote” plasma sources are frequently used, where the plasma is located at some distance from the surface to be treated or substrate on which a layer is being formed. The distance allows some filtering of the charged particles in the plasma. For example, the density of electrons and ions can be adjusted or removed from the generated plasma.

Typically, logic devices have used silicon as the active channel material. Increasingly, logic devices are using germanium-based layers as the semiconductor channel in advanced transistors. The germanium-based layers may include germanium or silicon-germanium alloys. Regardless of the composition of the channel material, the interface between the channel material and the gate dielectric layer must be passivated to yield improved electric performance.

What is needed is a system and methods that enable the in-situ doping of the interface while reducing the etching of the overlying dielectric. Such systems and mehods may include the use of direct or remote plasmas and the use of species that retard the etch rate of the dielectric.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Methods and apparatus for processing using a remote plasma source for the doping and passivation of semiconductor-dielectric interfaces are disclosed. The apparatus includes an outer chamber enclosing a substrate support, a plasma source (either a direct plasma or a remote plasma), and a showerhead. Other gas distribution and gas dispersal hardware may also be used. A substrate heater may be mounted in the substrate support. In some embodiments, a transport system moves the substrate support and is capable of positioning the substrate. The remote plasma source may be used to generate activated species operable to remove semiconductor oxide layers. Further, the remote plasma source may be used to generate activated species operable to provide a passivation of the cleaned semiconductor surface.

Methods are disclosed that discuss the use of blocking species that bind to the surface of the dielectric and retard the etching of the dielectric surface by the doping/passivating species. The surface of the dielectric may be exposed to the blocking species a plurality of times during the process to ensure that the surface is well protected.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a cross-sectional schematic diagram of a typical semiconductor device.

FIG. 2 illustrates a schematic diagram for plasma surface treatment according to some embodiments.

FIG. 3 illustrates a processing system enabling plasma surface treatment according to some embodiments.

FIG. 4 illustrates a flow chart of a method according to some embodiments. embodiments.

FIGS. 5A-5C illustrate an example of a process sequence for doping/passivating an interface formed between a semiconductor material and a dielectric material according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Before various embodiments are described in detail, it is to be understood that unless otherwise indicated, this invention is not limited to specific layer compositions or surface treatments. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, germanium, silicon-germanium alloys, gallium arsenide, indium gallium arsenide, indium gallium antimonide, silica, sapphire, zinc oxide, silicon carbide, aluminum nitride, Spinel, coated silicon, silicon on oxide, silicon carbide on oxide, glass, gallium nitride, indium nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

The term “remote plasma source” as used herein refers to a plasma (e.g., an rf or microwave generated plasma) located at a distance from a deposition or treatment location sufficient to allow some filtering of the plasma components. For example, the density of ions and electrons can be adjusted by distance, and electrons and ions can also be filtered out using suitable electrode configurations, such as a grounded metal showerhead so that only atomic or molecular radicals reach the substrate.

Scaling of the gate lengths and equivalent gate oxide thicknesses is forcing the replacement of silicon dioxide as a gate dielectric by materials having high-dielectric constants (i.e., high-k materials). The goals include reduction of leakage currents and meeting requirements of reliability. Some additional consideration in selecting suitable replacement materials include silicon related band offsets, permittivity, dielectric breakdown strength, interface stability and quality with silicon, and the effective masses of the carriers.

The term “dangling bond” will be understood to an unsatisfied valence on an immobilized atom associated with a material or layer (typically at or near the surface). Those skilled in the art will understand that this is a term of art and is not generally accepted to represent a physical configuration of the atom.

The term “doping/passivating species” is used herein to refer to atomic or molecular species that are able to diffuse through the dielectric material and bind to dangling bonds at the interface between the semiconductor channel material and the gate dielectric material.

The term “blocking species” is used herein to refer to atomic or molecular species that bind to the surface of the dielectric material and inhibit the etching of the dielectric material by the doping/passivating species.

Semiconductor Device Examples

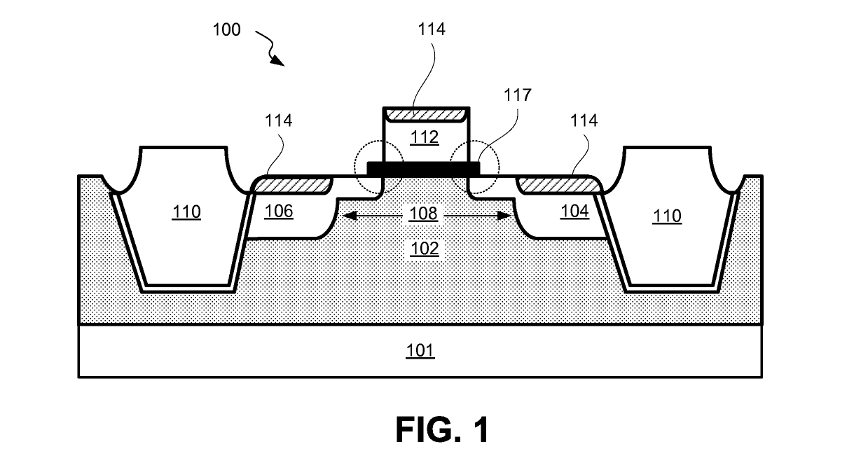

A brief description of semiconductor device examples is presented below to provide better understanding of various plasma surface treatments. Specifically, FIG. 1 illustrates a schematic representation of substrate portions including MOS device, 100, in accordance with some embodiments. The references below are made to positive metal-oxide semiconductor (PMOS) devices but other types of MOS devices can be used in the described processes and will be understood by one having ordinary skill in the art. MOS device 100 includes a p-doped substrate, 101, and an n-doped well, 102, disposed within substrate, 101. Substrate, 101, is typically a part of an overall wafer that may include other devices. Some of these devices may include silicon nitride, silicon oxide, polysilicon, or titanium nitride structures. P-doped substrate, 101, may include any suitable p-type dopants, such as boron and indium, and may be formed by any suitable technique. N-doped well, 102, may include any suitable n-type dopants, such as phosphorus and arsenic, and may be formed by any suitable technique. For example, n-doped well, 102, may be formed by doping substrate, 101, by ion implantation, for example.

MOS device, 100, also includes a conductive gate electrode, 112, that is separated from n-doped well, 102, by gate dielectric, 117. Gate electrode, 112, may include any suitable conductive material. In some embodiments, gate electrode, 112, may comprise polysilicon. In some embodiments, gate electrode, 112, may include polysilicon doped with a p-type dopant, such as boron. Gate dielectric, 117, is formed from a high-k material (e.g. hafnium oxide). Other dielectric materials include zirconium oxide or aluminum oxide. Typically, a semiconductor material with high mobility such as germanium or a silicon-germanium alloy (not shown) is formed beneath the gate dielectric.

MOS device, 100, also includes p-doped source region, 104, and drain region, 106, (or simply the source and drain) disposed in n-doped well, 102. Source, 104, and drain, 106, are located on each side of gate electrode, 112, forming channel, 108, within n-doped well, 102. Source, 104, and drain, 106, may include a p-type dopant, such as boron. Source, 104, and drain, 106, may be formed by ion implantation. After forming source, 104, and drain, 106, MOS device, 100, may be subjected to an annealing and/or thermal activation process.

In some embodiments, source, 104, drain, 106, and gate electrode, 112, are covered with a layer of self-aligned silicide portions, 114, which may be also referred to as salicide portions or simply salicides. For example, a layer of cobalt may be deposited as a blanket layer and then thermally treated to form these silicide portions, 114. Other suitable materials include nickel and other refractory metals, such as tungsten, titanium, platinum, and palladium. After forming the blanket layer from the suitable metal, the layer is subjected to rapid thermal process (RTP) to react the metal with silicon contained within gate electrode, 112, as well as within source, 104, and drain, 106, to form a metal silicide. The RTP process may be performed at 700° C. to 1000° C.

MOS device, 100, may also include shallow trench isolation (STI) structures, 110, disposed on both sides of source, 104, and drain, 106. STI structures, 110, may include liners formed on the side and bottom walls by, for example, thermal oxidation of silicon of n-doped well, 102. The main body of STI structures is formed by filling a trench within n-doped well, 102, with a dielectric material, such as silicon oxide. Silicon oxide may be filled using high density plasma (HDP) deposition process.

As shown in FIG. 1, gate dielectric, 117, may protrude beyond gate electrode, 112. As such, gate dielectric, 117, may need to be partially etched such that it does not extend past electrode, 112, and does not interfere with subsequent formation of liners and spacers on sidewalls of gate electrode, 112.

In some embodiments, the gate dielectric, 117, and/or the gate electrode, 112, may receive a surface plasma treatment to improve the performance of the device.

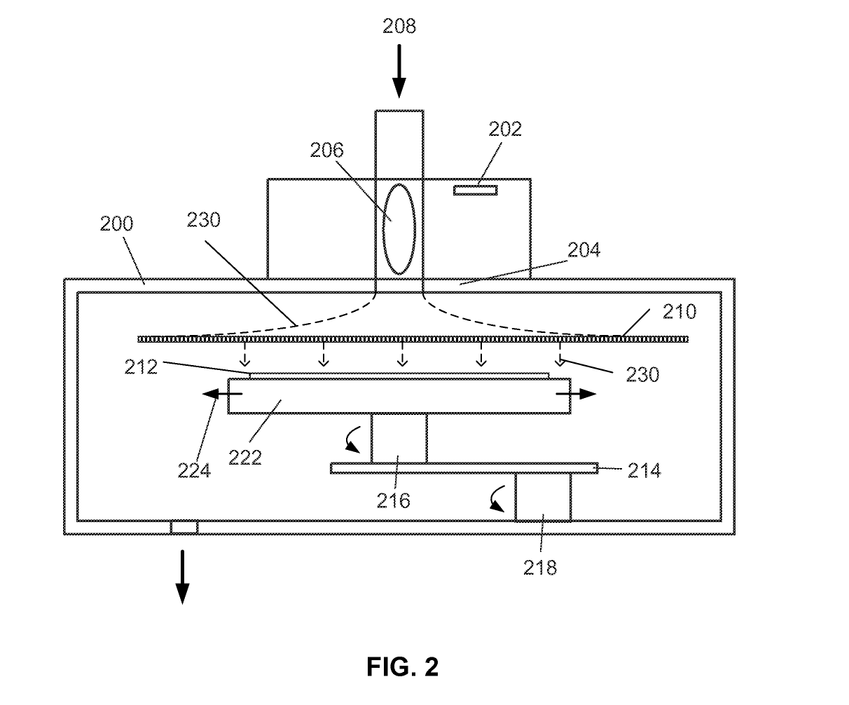

FIG. 2 illustrates the overall layout of some embodiments of a system enabling combinatorial processing using a remote plasma source. A discussion of the system may be found in co-owned U.S. patent application Ser. No. 13/328,129 filed on Dec. 16, 2011 which is herein incorporated by reference for all purposes. Portions of the '129 application are included herein to enhance the understanding of the present disclosure. A process chamber, 200, is provided. A remote plasma source, 202, is mounted on a chamber lid, 204, either directly as illustrated or through a short flange. The plasma, 206, is entrained into a central gas flow, 208, which is directed toward a showerhead, 210. The showerhead is disposed within the processing chamber between the remote plasma source and the substrate and is in close proximity to the substrate, 212. The showerhead further includes multiple regions, each region containing an inert gas port. The showerhead is operable to provide exposure of reactive species from the remote plasma source to regions of the substrate. A substrate positioning system, 214, can position the substrate, 212, directly under the showerhead, 210. As illustrated in FIG. 2, the substrate positioning system can provide two displaced axes of rotation, 216 and 218. The two-axis rotation configuration illustrated can provide 360° of rotation for the upper rotation (providing an angular coordinate) and 60° of rotation for the lower axis (approximating a radial coordinate) to provide all possible substrate positions. Alternatively, other positioning systems such as X-Y translators can also be used. In addition, substrate support, 222, may move in a vertical direction. It should be appreciated that the rotation and movement in the vertical direction may be achieved through known drive mechanisms which include magnetic drives, linear drives, worm screws, lead screws, a differentially pumped rotary feed through drive, etc.

The substrate support, 222, can include a substrate heater (e.g., resistive or inductive) and can be sized to be larger than the largest substrate to be processed. Substrate temperatures for most remote plasma applications are less than 500 C, although any suitable heater power and range of temperature control. The substrate support, 222, can also be configured to provide a gas purge flow, 224, for example from the edges of the support, using argon, helium, or any other gas that is not reactive under the process conditions.

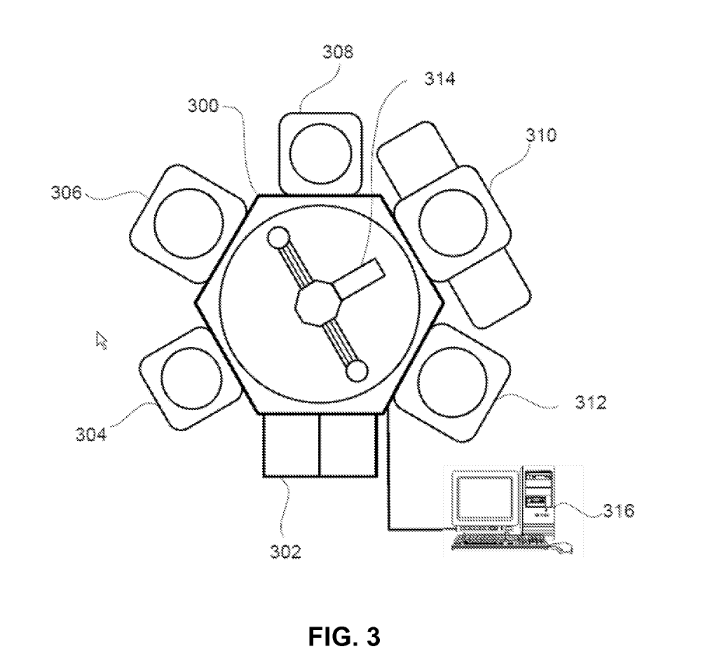

FIG. 3 is a simplified schematic diagram illustrating an integrated processing system in accordance with some embodiments of the invention. The processing system includes a frame, 300, supporting a plurality of processing modules. It will be appreciated that frame, 300, may be a unitary frame in accordance with some embodiments. In some embodiments, the environment within frame, 300, is controlled. A load lock, 302, provides access into the plurality of modules of the processing system. A robot, 314, provides for the movement of substrates (and masks) between the modules and for the movement into and out of the load lock, 302. Modules, 304-312, may be any set of modules and preferably include one or more processing modules. For example, module, 304, may be an orientation/degassing module, module, 306, may be a clean module, either plasma or non-plasma based, modules, 308, and/or 310, may be dual purpose modules. Module, 312, may provide conventional clean or degas as necessary.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device, 316, may control the processes of the processing system. Further details of one possible processing system are described in U.S. application Ser. Nos. 11/672,478 and 11/672,473, the entire disclosures of which are herein incorporated by reference. In a processing system, a plurality of methods may be employed to deposit material upon a substrate.

Plasmas are widely used for a variety of treatment and layer deposition tasks in semiconductor fabrication. These applications include subtractive processes such as wafer precleaning, contaminant removal, native oxide removal, photoresist removal, as well as treatment processes such as oxidation, nitridation, or hydridation of a layer both during and after formation. “Remote” plasma sources are frequently used, where the plasma is located at some distance from the surface to be treated or substrate on which a layer is to be formed. The distance allows some adjusting of the charged particles in the plasma. For example, the density of ions and electrons can be adjusted by distance, the electrons and ions can be removed from the generated plasma using suitable electrode configurations such as a grounded metal showerhead, so that, for example, only atomic radicals and molecule radicals (but not ions) reach the substrate.

The plasma generator for a remote plasma source can use any known means of coupling energy into atoms or molecules to ionize them and create a plasma. The energy source can be, for example, electromagnetic energy such as microwaves, radio frequency energy, or lasers.

Typically, systems using remote plasma sources were designed to treat the entire area of a substrate, such as a 300 mm wafer. Combinatorial processing is difficult and expensive when the entire area of a substrate can only receive a single process variation. Some embodiments of the present invention overcome this limitation by providing a remote plasma source, an associated substrate positioning system, and a site isolation system that allows a selected region of a substrate to be processed while the remaining regions of the substrate are protected from exposure to the plasma and reactive radical species unless or until such exposure is intended.

Accordingly, an apparatus for processing using remote plasma exposure of a substrate is disclosed. The apparatus comprises an outer chamber containing: a remote plasma source, a showerhead, and a transport system comprising a substrate support and capable of positioning the substrate. The plasma exposure process parameters can be varied. The plasma exposure process parameters comprise one or more of source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof.

In some embodiments, methods of varying surface exposure to a plasma or reactive radical species are provided. The methods comprise exposing a substrate to a plasma or reactive radical species from a remote plasma source under a first set of process parameters, and exposing a substrate to a plasma or reactive radical species from a remote plasma source under a second set of process parameters. The process parameters can be varied in a combinatorial manner. Typically, the process parameters comprise one or more of source gases for the plasma generator, plasma filtering parameters, exposure times, gas flow rates, frequencies, plasma generator powers, plasma generation methods, chamber pressures, substrate temperatures, distances between plasma source and substrate, substrate bias voltages, or combinations thereof.

In some embodiments, a layer can be exposed to a plasma surface treatment, thereby altering one or more of the layer's properties. Examples of suitable atoms include O, N, Cl, F, H, and the like. The atoms may be used to remove semiconductor oxide materials from the surface of the substrate. Examples of gases that may be used in the remote plasma source to generate the ions or reactive neutral species include H₂, H₂O, O₂, N₂, N₂O, NH₃, BCl₃, NF₃, H₂S, and the like. The concentration and composition of the various species generated in the plasma may be varied by varying a number of the process parameters as well as the gas composition. A description of using these parameters to influence the concentration and composition of the various species generated in the plasma may be found in U.S. patent application Ser. No. 14/051,287, filed on Oct. 10, 2013, and claiming priority to U.S. Provisional Application No. 61/780,128, filed on Mar. 13, 2013, each of which is herein incorporated by reference for all purposes.

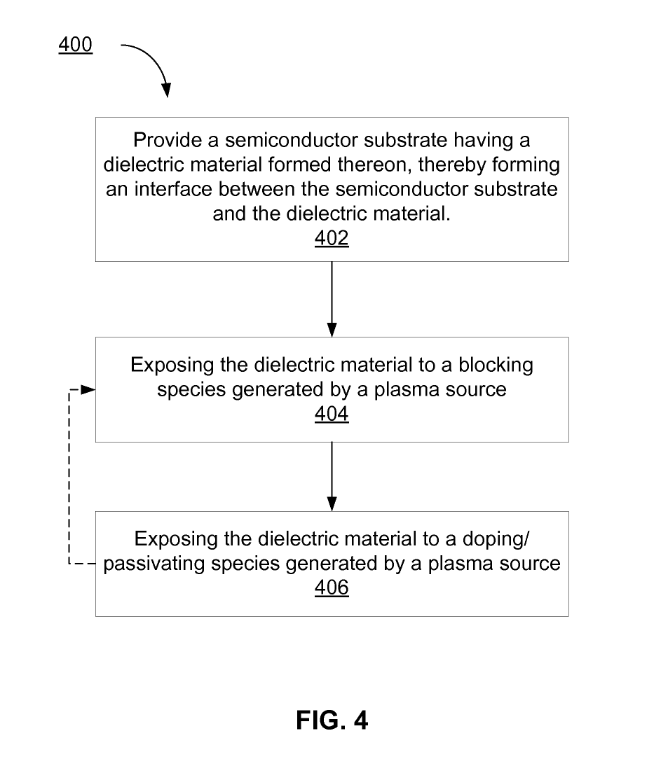

FIG. 4 illustrates a flow chart of a method according to some embodiments. In step 402, a semiconductor substrate is provided having a dielectric material formed thereon. The dielectric material forms an interface with the semiconductor substrate. Examples of suitable semiconductor substrates include silicon, germanium, and silicon-germanium alloys. Examples of suitable dielectric materials include aluminum oxide, barium strontium titanate, germanium oxide, hafnium oxide, silicon oxide, tantalum oxide, and titanium oxide. Typically, the dielectric material has a thickness of about 30A (as used herein, “A” denotes an Ångstrom unit=0.1 nm) and dielectric constants ranging from about 4 to about 25.

In step 404, the dielectric material is exposed to a blocking species generated by a plasma source. As discussed previously, the plasma source may include a remote plasma source or a direct plasma source. The system and plasma source may be employed as described earlier. The blocking species that are generated may include at least one of Al, B, C, GeOₓ, H, N, P, or S. Gases that may be used in the plasma source to generate the blocking species include trimethyl aluminum, B₂H₆, BF₃, BCl₃, CH₄, C₃H₆, C₂H₄, GeH₄, H₂, H₂O, N₂, N₂O, NH₃, NF₃, PH₃, or H₂S, among others. These gases are listed as examples. Those having skill in the art will understand that any known gas or precursor can be used to supply the blocking species. Those skilled in the art will understand that inert gases such as helium, neon, argon, krypton, and xenon may also be introduced into the plasma. Generally, these species are not active in the modification of the surface unless a bias voltage is applied to the substrate and ions of these inert gases are accelerated toward the surface. In some embodiments, the blocking species include hydrogen species. The hydrogen blocking species may be at least one of ions or neutral species. In some embodiments, the gas used to generate the hydrogen blocking species includes hydrogen gas.

In some embodiments, the blocking species react with the dielectric material and effectively form bonds between the blocking species and the dielectric material. The bonding results in a passivation of the dielectric material surface wherein the number of active binding sites is reduced. In some embodiments, hydrogen blocking species react with the dielectric material present on the surface and passivate the surface with Ge—H and/or Si—H bonds. The Ge—H and/or Si—H bonds will serve to retard the etching of the semiconductor surface during a subsequent doping/passivation step.

In step 406, the dielectric material with the blocking species attached thereon is exposed to a doping/passivation species generated by a plasma source. As discussed previously, the plasma source may include a remote plasma source or a direct plasma source. The system and plasma source may be employed as described earlier. The doping/passivation species that are generated may include at least one of Br, Cl, F, I, S, or Se. Gases that may be used in the plasma source to generate the blocking species include Br₂, HBr, Cl₂, HCl, F₂, HF, NF₃, I₂, HI, H₂S, or H₂Se, among others. Those having skill in the art will understand that any known gas or precursor can be used to supply the doping/passivation species. Those skilled in the art will understand that inert gases such as helium, neon, argon, krypton, and xenon may also be introduced into the plasma. Generally, these species are not active in the modification of the surface unless a bias voltage is applied to the substrate and ions of these inert gases are accelerated toward the surface. In some embodiments, the doping/passivation species include fluorine species. The fluorine doping/passivation species may be at least one of ions or neutral species. In some embodiments, the gas used to generate the fluorine doping/passivation species includes NF₃ gas.

In some embodiments, the doping/passivation species will diffuse through the dielectric material and bind to dangling bonds found at the semiconductor-dielectric material interface. Typically, these dangling bonds are formed by oxygen vacancies (typically <10 atomic %) due to differences in bonding coordination across the interface. The doping/passivation species may bind to the dangling bonds and improve the performance of the device.

In some embodiments, the doping/passivation species also react with the dielectric material to form volatile species that can be removed (e.g., by etching). In this application, it is desirable to remove the volatile species without etching the underlying dielectric material. In some embodiments, the blocking species are operable to retard the effective etching rate of the doping/passivation species on the dielectric material. Without being bound by theory, there are several mechanisms that may be responsible for reducing the etch rate of the doping/passivation species on the dielectric material. The doping/passivation species may react with the blocking species to form a volatile species that is removed from the chamber. This has effectively reduces the concentration of the doping/passivation species. The blocking species may bind to active sites on the surface of the dielectric material and effectively reduce the number of active sites that are available for the reaction with the doping/passivation species.

In some embodiments, the exposure to the blocking species and the exposure to the doping/passivation species can be repeated in a cyclical manner (as indicated in FIG. 4) to refresh the concentration of the blocking species on the surface of the dielectric to further control the etching of the dielectric surface by the doping/passivation species.

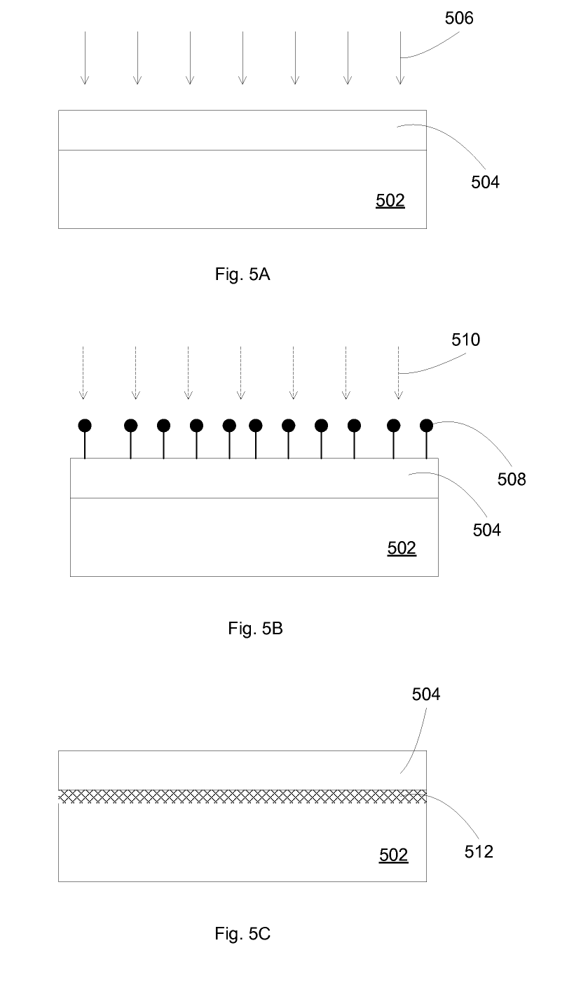

FIGS. 5A-5C illustrate an example of a process sequence for doping/passivating an interface formed between a semiconductor material and a dielectric material according to some embodiments.

In FIG. 5A, a semiconductor material, 502, is provided wherein a dielectric material, 504, has been formed thereon. Examples of suitable semiconductor substrates include silicon, germanium, and silicon-germanium alloys. Examples of suitable dielectric materials include aluminum oxide, barium strontium titanate, geranium oxide, hafnium oxide, silicon oxide, tantalum oxide, and titanium oxide.

Typically, the dielectric material has a thickness of about 30A and dielectric constants ranging from about 4 to about 25. In some embodiments, the dielectric material is exposed to blocking species, 506, generated from a plasma source. As discussed previously, the plasma source may be a remote plasma source or a direct plasma source. The blocking species that are generated may include at least one of Al, B, C, GeOₓ, H, N, P, or S. Gases that may be used in the plasma source to generate the blocking species include trimethyl aluminum, B₂H₆, BF₃, BCl₃, CH₄, C₃H₆, C₂H₄, GeH₄, H₂, H₂O, N₂, N₂O, NH₃, NF₃, PH₃, or H₂S, among others. These gases are listed as examples. Those having skill in the art will understand that any known gas or precursor can be used to supply the blocking species. Those skilled in the art will understand that inert gases such as helium, neon, argon, krypton, and xenon may also be introduced into the plasma. Generally, these species are not active in the modification of the surface unless a bias voltage is applied to the substrate and ions of these inert gases are accelerated toward the surface. In some embodiments, the blocking species bind to the surface of the dielectric material and form a blocking layer on the surface (indicated by elements 508 in FIG. 5B).

In FIG. 5B, the dielectric material, 504, (with the blocking layer, 508, formed thereon) is exposed to doping/passivation species, 510, generated from a plasma source. As discussed previously, the plasma source may be a remote plasma source or a direct plasma source. The system and plasma source may be employed as described earlier. The doping/passivation species that are generated may include at least one of Br, Cl, F, I, S, or Se. Gases that may be used in the plasma source to generate the blocking species include Br₂, HBr, Cl₂, HCl, F₂, HF, NF₃, I₂, HI, H₂S, or H₂Se, among others. Those having skill in the art will understand that any known gas or precursor can be used to supply the doping/passivation species. Those skilled in the art will understand that inert gases such as helium, neon, argon, krypton, and xenon may also be introduced into the plasma. Generally, these species are not active in the modification of the surface unless a bias voltage is applied to the substrate and ions of these inert gases are accelerated toward the surface.

In FIG. 5C, the doping/passivation species have diffused through the dielectric material, 504, to passivate dangling bonds at the interface between the semiconductor material, 502 and the dielectric material, 504. This passivated interface is illustrated by element 512 in FIG. 5C. The passivation at the interface between the semiconductor material and the dielectric material will improve the performance of the device.

In some embodiments, the semiconductor material, 502, is a silicon substrate and the dielectric material, 504, is silicon dioxide. The silicon dioxide can be exposed to a blocking species generated by a plasma source. In some embodiments, the blocking species includes hydrogen and the plasma source is a remote plasma source. The substrate may be heated to a temperature between 25 C and 400 C. Typical plasma power can vary from about 100 W to about 3000 W. The exposure time can vary between about 30 seconds and 2 minutes. The pressure may be between about 0.5 Torr and 5 Torr. The hydrogen blocking species may form Si—H bonds at the surface of the dielectric material. In some embodiments, silicon dioxide (with the Si—H bonds formed thereon) can be exposed to a doping/passivation species generated by a plasma source. In some embodiments, the doping/passivation species includes fluorine and the plasma source is a remote plasma source. The fluorine doping/passivation species may be generated from NF₃ supplied to the plasma source. In some embodiments, the fluorine doping/passivation species react with the hydrogen bonded to the dielectric to form volatile species (e.g. HF) that are removed from the chamber. These reactions effectively reduce the concentration of fluorine species that are available to interact with the dielectric material. In some embodiments, the fluorine doping/passivation species diffuse through the dielectric material and bind to dangling bonds formed at the interface between the semiconductor material and the dielectric material, thereby passivating the dangling bonds. In some embodiments, the steps of exposing the dielectric material to hydrogen blocking species and exposing the dielectric material to fluorine doping/passivation species are repeated in a cyclical manner to refresh the concentration of the hydrogen blocking species on the surface of the dielectric to further control the etching of the dielectric surface by the fluorine doping/passivation species.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method comprising:
providing a semiconductor substrate,
forming a dielectric layer on the substrate, wherein an interface is formed between the substrate and the dielectric layer;
exposing the dielectric layer to a blocking species,
wherein the blocking species is generated using a plasma source,
wherein at least a portion of the blocking species is operable to bind to at least a portion of a surface of the dielectric layer; and
exposing the dielectric layer to a doping/passivating species,
wherein the doping/passivating species are formed using a plasma source,
wherein at least a first portion of the doping/passivating species reacts with the portion of the blocking species bound to at least a portion of a surface of the dielectric layer,
wherein at least a second portion of the doping/passivating species diffuse through the dielectric layer to the interface formed between the substrate and the dielectric layer.

2. The method of claim 1, wherein the substrate comprises at least one of silicon oxide, germanium oxide, or an oxide of a silicon-germanium alloy.

3. The method of claim 2, wherein the substrate comprises silicon.

4. The method of claim 1, wherein the dielectric layer comprises at least one of aluminum oxide, barium strontium titanate, germanium oxide, hafnium oxide, silicon oxide, tantalum oxide, or titanium oxide.

5. The method of claim 4, wherein the dielectric layer comprises silicon oxide.

6. The method of claim 1, wherein the blocking species comprises at least one of Al, B, C, GeOₓ , H, N, P, or S.

7. The method of claim 6, wherein the blocking species comprises H.

8. The method of claim 1, wherein a gas used to generate the blocking species comprises at least one of trimethyl aluminum, B₂H₆, BF₃, BCl₃, CH₄, C₃H₆, C₂H₄, GeH₄, H₂, H₂O, N₂, N₂O, NH₃, NF₃, PH₃, or H₂S.

9. The method of claim 7, wherein the blocking species comprises H₂.

10. The method of claim 1, wherein the doping/passivating species comprises at least one of Br, Cl, F, I, S, or Se.

11. The method of claim 10, wherein the blocking species comprises F.

12. The method of claim 1, wherein a gas used to generate the blocking species comprises at least one of Br₂, HBr, Cl₂, HCl, F₂, HF, NF₃, I₂, HI, H₂S, or H₂Se.

13. The method of claim 12, wherein the blocking species comprises NF3.

14. The method of claim 1, wherein the exposing is performed at a temperature between 25 C and 400 C.

15. The method of claim 14, wherein the exposing is performed at a temperature between 100 C and 300 C.

16. The method of claim 1, wherein the exposing is performed at a pressure between 0.5 Torr and 5 Torr.

17. The method of claim 16, wherein the exposing is performed at a pressure between 0.5 Torr and 2 Torr.

18. The method of claim 1, wherein the exposing is performed for a time between 30 seconds and 60 minutes.

19. The method of claim 18, wherein the exposing is performed for a time between 30 seconds and 2 minutes.

20. A method comprising:
providing a silicon substrate,
forming a silicon oxide dielectric layer on the substrate,
wherein an interface is formed between the silicon substrate and the silicon oxide dielectric layer;
exposing the silicon oxide dielectric layer to a hydrogen blocking species,
wherein the hydrogen blocking species are generated using a plasma source, wherein at least a portion of the hydrogen blocking species are operable to bind to at least a portion of a surface of the silicon oxide dielectric layer; and
exposing the silicon oxide dielectric layer to a fluorine doping/passivating species,
wherein the fluorine doping/passivating species are generated using a plasma source, wherein at least a first portion of the fluorine doping/passivating species reacts with the portion of the hydrogen blocking species bound to at least a portion of a surface of the dielectric layer,
wherein at least a second portion of the fluorine doping/passivating species diffuse through the silicon oxide dielectric layer to the interface formed between the silicon substrate and the silicon oxide dielectric layer.
